(19) United States
(12) Patent Application Publication
(10) Pub. No.: US 2005/0111184 A1
(43) Pub. Date: May 26, 2005

(54) Cooling of a computer environment

(75) Inventors: David Trevor Cliff, Southville (GB); Andrew Robert Byde, Wales (GB)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: Hewlett-Packard Development Company, L.P.

(21) Appl. No.: 10/839,125

(22) Filed: May 6, 2004

(30) Foreign Application Priority Data
Oct. 31, 2003 (GB) 0325477.8

(51) Int. Cl. H05K 7/20

(52) U.S. Cl. 361/688

(57) ABSTRACT

A method for controlling the cooling of a computing environment comprising: deploying at least one portable device to separate, at least partially, a first portion of the computing environment from an adjacent portion of the computing environment; and increasing a mass flow of air to/from the first, at least partially, separated portion.

### FIELD OF THE INVENTION

Embodiments of the invention relate to a method for controlling the cooling of a computing environment, a system for controlling the cooling of a computing environment and a portable robotic device for controlling the cooling of a portion of a computing environment.

### BACKGROUND TO THE INVENTION

A computing environment comprises a plurality of computers at one location. There may be hundreds or thousands of computers. In a utility data centre (UDC) or on demand computer (ODC) the computers are used as a computing resource which can be dynamically allocated in part or in whole to customers according to demand.

The computers are typically arranged in stacks from the floor close to the ceiling. The stacks are arranged in aisles with corridors between the aisles that allow human access. The computing environment will typically be a closed room and will have an integrated air conditioning system to maintain the room's temperature within a range suitable for the operation of the computers.

A problem with computing environments is that there may be a local increase in temperature because of unequal processing loads within the computers of the computing environment or because of a failure of part of the air conditioning system.

The problem of local temperature increases could be addressed by cooling the whole of the environment as if it were operating at maximum processing power. However, this is uneconomical because the cooling of the environment is not optimal if the environment is not operating at full processing power.

The problem of failure of a part of the air conditioning system could be addressed by installing a secondary back-up air conditioning system that is the same as the primary air conditioning system. This would be expensive.

### BRIEF DESCRIPTION OF THE INVENTION

According to one embodiment there is provided a method for controlling the cooling of a computing environment comprising: deploying at least one portable device to separate, at least partially, a first portion of the computing environment from an adjacent portion of the computing environment; and increasing a mass flow of air to (or from) the first, at least partially, separated portion.

According to another embodiment there is provided a system for controlling the cooling of a computing environment comprising: at least one portable device; means for deploying one or more of the plurality of portable devices to separate a first portion of the computing environment from an adjacent portion or portions of the computing environment; and means for increasing the mass flow of air to and/or from the first portion.

According to another embodiment there is provided a robot for controlling the cooling of a portion of a computing environment comprising: means for controlling the air flow from the portion of the computing environment.

According to another embodiment there is provided a method for controlling the cooling of a computing environment comprising: deploying at least one portable device to control the flow of air between a first portion of the computing environment and an adjacent portion of the computing environment; and increasing the mass flow of air to the first portion.

According to another embodiment there is provided a method for controlling the cooling of a computing environment comprising: deploying at least one portable device to control the flow of air between a first portion of the computing environment and an adjacent portion of the computing environment; and increasing the mass flow of air from the first portion.

According to another embodiment there is provided a system for controlling the cooling of a computing environment comprising: a plurality of portable devices; means for deploying one or more of the plurality of portable devices to control the flow of air between a first portion of the computing environment and an adjacent portion or portions of the computing environment; and means for increasing the mass flow of air to the first portion.

According to another embodiment there is provided a system for controlling the cooling of a computing environment comprising: a plurality of portable devices; means for deploying one or more of the plurality of portable devices to control the flow of air between a first portion of the computing environment and an adjacent portion or portions of the computing environment; and means for increasing the mass flow of air from the first portion.

According to another embodiment there is provided a method for controlling the cooling of a computing environment comprising: controlling the air flow from a portion of the computing environment using at least one portable robot device.

Embodiments of the invention consequently enable localised cooling of a portion of a computing environment.

### BRIEF DESCRIPTION OF THE DRAWINGS

FIG. 1 schematically illustrates a computing environment;

FIG. 2 schematically illustrates a system for controlling the cooling of the computing environment;

FIG. 3 schematically illustrates a robot;

FIG. 4A illustrates a separator having an extendible partition;

FIGS. 4B and 4C illustrate a separator 40 having rotatable vertical slats;

FIG. 5 illustrates a simple deployment of two robots 30 to separate a portion of a computing environment; and

FIG. 6 illustrates a ‘daisy-chaining’ of robots.

### DETAILED DESCRIPTION OF EMBODIMENTS OF THE INVENTION

The following paragraphs describe a method for controlling the cooling of a computing environment by deploying at least one portable robot device that controls the flow of air within the computing environment. This enables the localised cooling of a portion of a computing environment. A deployed robot may separate, at least partially, a first portion of the computing environment from an adjacent portion of the computing environment and thereby damp airflow within the computing environment. The robot may alternatively or in addition increase the mass flow of air from the first portion by extracting air from the first portion and venting that air outside the first portion.

It should be appreciated that separation does not necessarily imply complete physical separation.

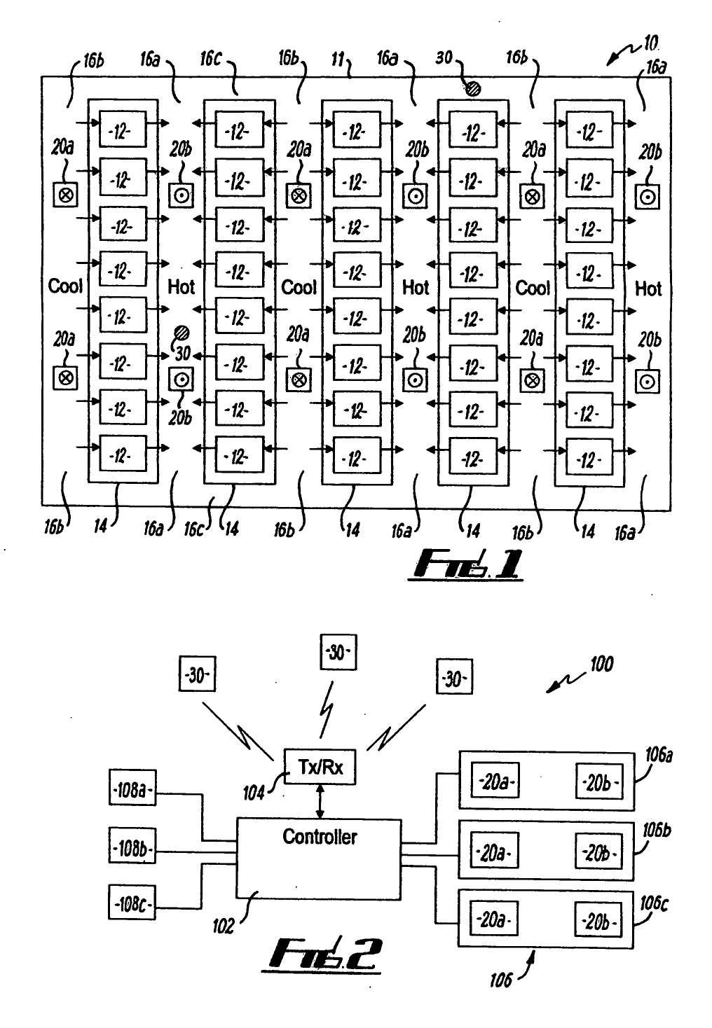

FIG. 1 schematically illustrates a computing environment 10. A utility data centre (UDC) or on demand computer (ODC) are exemplary types of computing environments 10.

The particular computing environment 10 illustrated comprises an enclosed room 11 with stacks 12 of computers arranged in an array of aisles 14 with corridors 16 between the aisles 14 and an integrated air conditioning system 106. Other computing environments may have differently arranged computer stacks 12.

The computer stacks 12 draw air from the corridors 16a and expel air to the corridors 16b. This circulation of air cools the circuitry within the computers by transferring heat to the expelled air. The corridors 16a would be relatively ‘cool’ and the corridors 16b would be relatively ‘hot’ in the absence of air conditioning.

In this configuration of computer environment 10, the air conditioning system extracts air from the ‘hot’ corridors 16b, cools that air using air cooling units (not shown) and injects the cooled air into the ‘cool’ corridors 16a. The air conditioning system 106 has air extraction units 20b positioned with air inlets in the ceiling of the ‘hot’ corridors 16b and injection units 20a with vents in the ceiling of the ‘cold’ corridors 16a.

The corridors 16a and 16b have interlinking runways 16c that allow portable robot devices (robots) 30 to move within the computing environment 10 via the corridors 16a, 16b and the runways 16c.

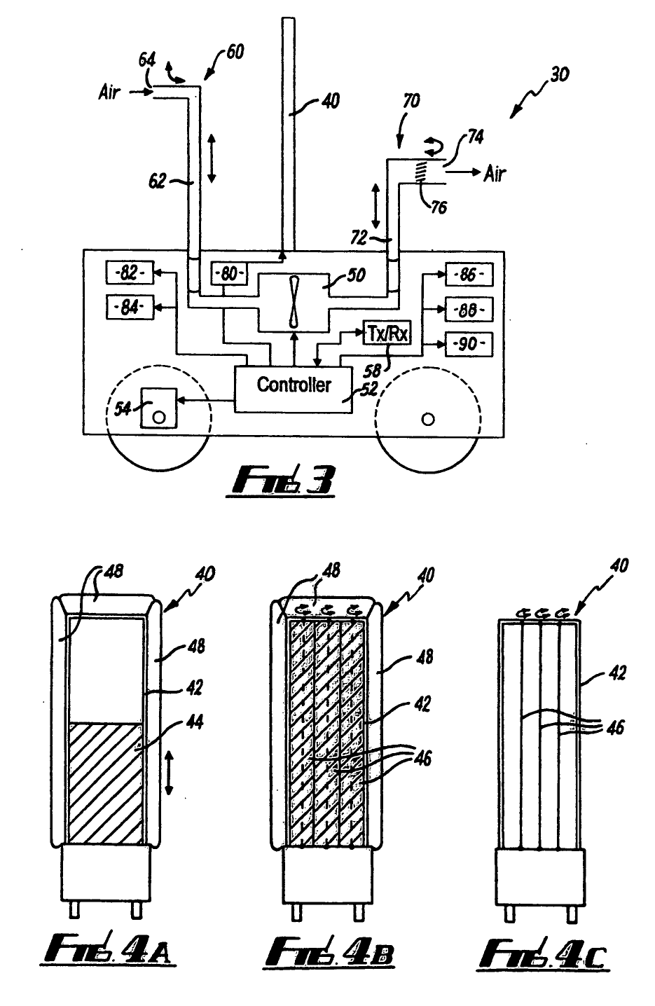

One or more robots 30 may move independently within the computing environment 10. These robots 30 may be permanently resident within the computing environment or may be introduced when required to control the cooling of a portion of a computing environment. A robot 30 is schematically illustrated in FIG. 3.

The robot 30 comprises: a controllable separator 40; an air flow engine 50; an inlet 60; a vent 70; a motor 54, a controller 52, a radio transceiver 58 and various drive mechanisms 80, 82, 84, 86, 88, 90.

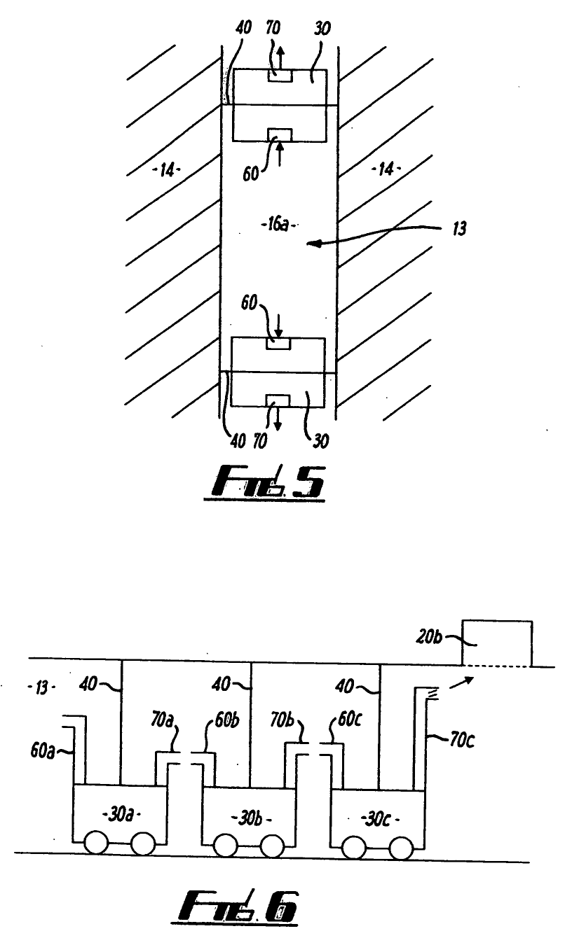

The controllable separator 40 provides means for separating one portion of the computing environment 10 from an adjacent portion of the computing environment 10. Separation does not necessarily imply complete physical separation as the separator 40 is used as a windbreak for damping air currents within the computing environment 10. The separator 40 comprises a vertical rectangular frame 42. In one embodiment, illustrated in FIG. 4A, a moveable partition can be extended vertically within the frame when the separator 40 is operational and can be retracted when the separator 40 is not operational. FIG. 4A illustrates a snap-shot of the controllable separator as the partition 44 is being extended upwards. In another embodiment, illustrated in FIGS. 4B and 4C, a series of parallel vertical slats 46 supported within the frame 42 are rotatable in unison, when the separator 40 is operational, to form a solid partition as illustrated in FIG. 4B. The height of the frame 42 is typically the same height or taller that the height of the computer stacks 12.

The frame 42 is, in this example, expandable. When expanded the width of the frame is substantially the same as the width of a corridor 16 and the top of the expanded frame is substantially at the ceiling of the room 11. The expansion may be achieved by inflating balloons 48 that extend along the exterior of the frame 42. These balloons 48 may be inflated when the separator 40 is operational and deflated when the separator is not operational. Although balloons are illustrated on the sides and top of the frame 42, in other embodiments there may only be balloons on the sides of the frame 42.

The expansion of the frame 42 is an optional feature and whether it is present or not the separator 40 provides means for substantially separating one portion of the computing environment from an adjacent portion of the computing environment.

The controller 52 controls the operation of the separator 40 using a drive mechanism 80. The drive mechanism 80 provides a mechanism for raising and lowering the partition 44 or rotating the vertical slats 46 in unison. It may also drive the inflation of the balloons 48, for example, by bleeding air from the air flow engine 50 and control the deflation of the balloons 48.

The air flow engine 50 in combination with the inlet 60 and vent 70 provide means for increasing the mass flow of air from the portion of the computing environment separated by the operational separator 40. The engine 50 draws air into the inlet 60 and exhausts it through the outlet 70.

The inlet 60 comprises a movable conduit 62. The conduit 62, in this example is solid and an inverted ‘L’ shape. The conduit 62 may be extended vertically upwards and downwards by a drive mechanism 82 under the control of the controller 52. This extends the vertical shaft of the L-shape. Thus the height at which air is extracted can be controlled. This may, for example, allow the orifice 64 of the inlet to be placed where there is a local increase in temperature e.g. adjacent overheating computers. The conduit may be rotated about the vertical shaft of the L-shape by a drive mechanism 84 under the control of controller 52. This positions the orifice 64 of the inlet 60. Other types of conduit may also be used. For example, the conduit 62 may, in other embodiments, be a flexible tube the end of which is attached to an extendible and rotatable support.

The vent 70 comprises a movable conduit 72. The conduit 72, in this example is an inverted ‘L’ shape. The conduit 72 may be extended vertically upwards and downwards by a drive mechanism 86 under the control of the controller 52. This extends the vertical shaft of the L-shape. Thus the height at which air is vented by the robot 30 can be controlled. This may, for example, allow the orifice 74 of the inlet to be placed adjacent the inlet to an air extraction unit 20b of the air conditioning system. The conduit 72 may be rotated about the vertical shaft of the L-shape by a drive mechanism 88 under the control of the controller 52. This positions the orifice 74 of the vent 70. The vent 70 also has controllable rudders 76 at the orifice 74 for directing the exhausted air flow. These rudders 76 are controlled by a drive mechanism 90 under the control of the controller 52. For example, the conduit 72 may, in other embodiments, be a flexible tube the end of which is attached to an extendible and rotatable support.

The air inlet 60 and air vent 70 are independently manoeuvrable in a manner similar to a periscope. They can be moved up and down and swivelled around by the controller 52 until they are in a desired position. The rudders 76 of the air vent 70 operate in a similar manner to the rudders of a car's air conditioning system.

The motor 54 is controlled by controller 52 and provides locomotive means for moving the robot 30. There will also be a steering mechanism (not shown) for controlling the direction of motion of the robot 30. In this example the robot moves on wheels but it may move on any suitable traction device such as, for example, caterpillar tracks.

The radio transceiver 58 provides communication means via which the controller 52 can communicate with and control the robot 30 can be controlled.

The controller 52 controls the motor 54 to move the robot 30 to a desired position, controls the extension and expansion of the separator 40, controls the position of the inlet 60, controls the position of the vent 70 and the configuration of the rudders of the vent 70 and activates the air flow engine 50.

The robot may optionally comprise a temperature sensor (not shown) electrically connected to the controller 52. This temperature sensor may be placed on the top of the inlet 60. The temperature sensor may be used to correctly position the orifice 64 of the inlet 60.

FIG. 2 schematically illustrates a system 100 for controlling the cooling of the computing environment 10.

The system comprises a central controller 102, a radio transceiver 104, a plurality of robots 30, an air conditioning system 106 having a plurality of air conditioning units 106a, 106b, 106c for cooling different portions of the computing environment 10 and a plurality of temperature sensors 108a, 108b and 108c for measuring the temperature of different portions of the computing environment 10. The temperature sensors 108 may be statically mounted within the computing environment 10 or each of the temperature sensors 108 may be attached to a robot 30 moving within the computing environment 10.

The controller 102 detects a portion 13 of the computing environment that requires additional cooling.

The controller 102 may detect the portion 13 that needs cooling from inputs received from the temperature sensors 108. These inputs may be obtained through the radio transceiver 104 if the temperature sensors 108 are mounted on robots 30 or via wires if the temperature sensors are static. The controller 102 detects the portion by determining if the air temperature sensed by the temperature sensor at that portion exceeds a threshold value.

Alternatively, the controller 102 may detect the portion 13 that needs cooling from inputs received from the air-conditioning units 106. The controller 102 may, for example, identify a malfunctioning air conditioning unit by detecting a variation in electrical power drawn by the unit. The controller 102 is operable to associate the malfunctioning of an air conditioning unit 106 with a portion or portions of the computing environment 10.

The controller 102 deploys one or more of the robots using the radio transceiver 104 to communicate with the robots 30. The robots are controlled to separate the portion 13 of the computing environment that requires cooling from an adjacent portion of the computing environment 10.

FIG. 5 illustrates the simple deployment of two robots 30 to separate a portion 13 of a corridor 16b. The robots are first manoeuvred into position and the separator is then activated and expanded.

The controller 102 then controls the cooling of the separated portion.

The controller 102 may increase the mass flow of hot air from that portion 13 by increasing the work done by the air extraction units 20b that have inlets within that portion.

The controller 102 may alternatively or in addition increase the mass flow of cold air to that portion 13 by increasing the work done by the air injection units 20a that have inlets within that portion.

The controller 102 may alternatively or in addition increase the mass flow of hot air from that portion 13 by using one or more robots 30 to extract air from that portion and vent it outside the portion 13. In the example illustrated in FIG. 5, the robots extract hot air from the portion 13 using theirs air flow engines 50. In other embodiments one or both robots 30 may inject cool air into the portion 30 using their air floe engines 50.

FIG. 6 illustrates a more complex deployment of robots which are ‘daisy-chained’ together. The robots are positioned in series such that an inlet 60a of a first robot 30a in the series extracts air from the separated portion 13 using its air flow engine 50 and vents it through its vent 70a into the inlet 60b of a second robot 30b in the series. The second robot 30b in the series uses its air flow engine to vent the received air through its vent 70b into the inlet 60c of a third robot in the series. The third robot 30c in the series uses its air flow engine 50 to vent the received air through its vent 70c towards an inlet to an air extraction unit 20b. Thus the inlet of each robot in the series receives air from a vent of the robot preceding it in the series, and the vent of a last robot in the series vents air towards an inlet to the air extraction unit.

‘Daisy-chaining’ may also be used to provide cool air to a separated portion 13. The robots are positioned in series such that an inlet 60a of a first robot 30a in the series extracts air from the outlet of an air injection unit 20a using its air flow engine 50 and vents it through its vent into the inlet of a second robot in the series. The second robot in the series uses its air flow engine 50 to vent the received cool air through its vent into the inlet of a third robot in the series. The third robot in the series uses its air flow engine 50 to vent the received cool air through its vent 70c into the separated portion 13. Thus the inlet of each robot in the series receives air from a vent of the robot preceding it in the series.

The central controller 102 may have a user interface (not shown) that allows an operator to remotely control the robots 30 by providing commands to the robots 30 using the radio transceiver. The operator would manually steer the robot 30 to its location, then position the inlet 60, position the vent 70, position the separator 60 and them activate the air flow engine 50.

Alternatively, the controller 102 may have a user interface (not shown) that allows an operator to activate semi-autonomous robots 30 by indicating the location to which a robot 30 should move to a robot via the radio transceiver 104. The robot 30 would determine a route to that location and move itself to that position along the determined route.

Alternatively, the robots 30 may be fully autonomous. The robot 30 itself may sense a temperature increase and act to reduce that temperature. In this case a central controller 102 may not be required.

It should be appreciated that the invention has been described with reference to particular non-limiting examples. The invention may be used in any appropriate computing environment and not necessarily the computing environment described. The invention may make use of any suitable portable robot device that controls the cooling of a portion of a computing environment and not necessarily the robot described.

Although reference in the preceding paragraphs is made to ‘air’, this term includes any suitable gas atmosphere used within a computing environment. It particularly includes this meaning when used in the claims. It is for example conceivable that the computing environment could have its own re-circulated gas atmosphere the composition of which is chosen for its cooling and/or fire retardant properties.

Although embodiments of the present invention have been described in the preceding paragraphs with reference to various examples, it should be appreciated that modifications to the examples given can be made without departing from the scope of the invention as claimed.

1. A method for controlling the cooling of a computing environment comprising:
deploying at least one portable device to separate, at least partially, a first portion of the computing environment from an adjacent portion of the computing environment; and
increasing a mass flow of air to/from the first, at least partially, separated portion.

2. A method as claimed in claim 1, wherein deploying the at least one portable device, at least partially, thermally isolates the first portion from the adjacent portion.

3. A method as claimed in claim 1, wherein deploying the at least one portable device to separate, at least partially, the first portion from an adjacent portion damps air currents within the computing environment.

4. A method as claimed in claim 1, wherein increasing the mass flow of air to the separated portion comprises increasing the output from an air cooling unit that vents to the first portion.

5. A method as claimed in claim 1, wherein increasing the mass flow of air from the first portion comprises increasing the input to an air extraction unit that intakes from the first portion.

6. A method as claimed in claim 1, wherein increasing the mass flow of air from the first portion involves extracting air from the first portion and venting that air outside the first portion using at least one portable device.

7. A method as claimed in claim 1, wherein increasing the mass flow involves deploying a multiplicity of portable devices in series such that an inlet of a first portable device in the series extracts air from the first portion, the inlet of each other portable device in the series receives air from a vent of the portable device preceding it in the series, and the vent of a last portable device in the series vents air towards an inlet to an air extraction unit.

8. A method as claimed in claim 1, further comprising sensing a temperature rise at a location within the computing environment and deploying the at least one portable device to separate a portion of the computing environment comprising that location.

9. A method as claimed in claim 1, further comprising sensing a malfunction of an air conditioning unit or air extraction unit and deploying the plurality of portable devices to separate a portion of the computing environment served by that unit.

10. A method as claimed in claim 1, further comprising separating the portion of the computing environment by using the at least one portable devices to provide a partition.

11. A system for controlling the cooling of a computing environment comprising:
at least one portable device;
means for deploying one or more of the plurality of portable devices to separate a first portion of the computing environment from an adjacent portion or portions of the computing environment; and
means for increasing the mass flow of air to/from the first portion.

12. A system as claimed in claim 11, wherein the means for increasing the mass flow of air to and/or from the first portion comprises one or more air conditioning units or air extraction units.

13. A system as claimed in claim 11, wherein the means for increasing the mass flow of air to and/or from the first portion comprises one or more of the plurality of portable devices.

14. A system as claimed in claim 11, wherein each portable device comprises an inlet, a vent, and an engine for drawing air into the inlet and exhausting it through the outlet.

15. A system as claimed in claim 14, wherein the inlet is comprised in a first movable conduit and the portable device comprises motive means for moving the first conduit and thereby positioning the inlet.

16. A system as claimed in claim 14, wherein the vent is comprised in a second movable conduit and the portable device comprises motive means for moving the second conduit and thereby positioning the vent.

17. A system as claimed in claim 16, wherein the vent includes controllable rudders for directing the exhausted air flow and the portable device comprises motive means for moving the controllable rudders.

18. A system as claimed in claim 14, wherein each portable device comprises locomotive means for moving the portable device and a controller for controlling the position of the portable device, wherein a first and a second portable device are operable to assume a position relative to each other that enables air to be extracted from the first portion by the first portable device and vented to the inlet of the second portable device outside the first portion.

19. A system as claimed in claim 11, wherein the system comprises a detector for detecting when a portion of the computer environment requires additional cooling and means for automatically deploying at least one portable device using locomotive means within that portable device.

20. A system as claimed in claim 19, wherein the detector detects the location of a temperature rise within the computer environment and the system cools the portion of the computer environment where the rise has occurred.

21. A system as claimed in claim 19, wherein the detector detects where a malfunction of air-conditioning of the computer environment occurs and the system cools the portion of the computer environment affected by the malfunction.

22. A system as claimed in claim 11, wherein each portable device is a remotely deployable robot.

23. A system as claimed in claim 11, wherein each portable device is an autonomously deployable robot.

24. A system as claimed in claim 11 wherein at least one portable device comprises a controllable partition.

25. A system as claimed in claim 24, where the controllable partition is a controllable windbreak for damping air currents within the computing environment.

26. A system as claimed in claim 24, where the controllable partition is extendible and/or expandable.

27. A system as claimed in claim 11, wherein the computing environment comprises stacks of computers arranged in an array of aisles with corridors between the aisles.

28. A portable device for use in the system as claimed in claim 11.

29. A robot for controlling the cooling of a portion of a computing environment comprising:
means for controlling the air flow from the portion of the computing environment.

30. A robot as claimed in claim 29, comprising:
means for separating, at least partially, the portion of the computing environment from an adjacent portion of the computing environment; and
means for increasing the mass flow of air from the separated portion.

31. A robot as claimed in claim 30, wherein the means for increasing the mass flow of air comprises an inlet, a vent, and an engine for drawing air into the inlet and exhausting it through the outlet.

32. A robot as claimed in claim 31, wherein the inlet is part of a first movable conduit and the robot comprises motive means for moving the first conduit and thereby positioning the inlet.

33. A robot as claimed in claim 32, wherein the vent is part of a second movable conduit and the robot comprises motive means for moving the second conduit and thereby positioning the vent.

34. A robot as claimed in claim 33, wherein the vent includes controllable rudders for directing the exhausted air flow and the robot comprises motive means for moving the controllable rudders.

35. A robot as claimed in claim 29, further comprising locomotive means for moving the robot and a controller for controlling the position of the robot.

36. A robot as claimed in claim 35 further comprising communication means by which the robot can be controlled.

37. A robot as claimed in claim 29, further comprising a temperature detector.

38. A robot as claimed in claim 29, further comprising a controllable partition for damping air currents within the computing environment.

39. A robot as claimed in claim 38, where the controllable partition is extendible and/or expandable.

40. A robot as claimed in claim 29, comprising:
means for separating, at least partially, the portion of the computing environment from an adjacent portion of the computing environment; and
means for increasing the mass flow of air to the separated portion.

41. A method for controlling the cooling of a computing environment comprising:
deploying at least one portable device to control the flow of air between a first portion of the computing environment and an adjacent portion of the computing environment; and
increasing the mass flow of air to the first portion.

42. A method for controlling the cooling of a computing environment comprising:
deploying at least one portable device to control the flow of air between a first portion of the computing environment and an adjacent portion of the computing environment; and
increasing the mass flow of air from the first portion.

43. A system for controlling the cooling of a computing environment comprising:
a plurality of portable devices;
means for deploying one or more of the plurality of portable devices to control the flow of air between a first portion of the computing environment and an adjacent portion or portions of the computing environment; and
means for increasing the mass flow of air to the first portion.

44. A system for controlling the cooling of a computing environment comprising:
a plurality of portable devices;
means for deploying one or more of the plurality of portable devices to control the flow of air between a first portion of the computing environment and an adjacent portion or portions of the computing environment; and
means for increasing the mass flow of air from the first portion.

45. A method for controlling the cooling of a computing environment comprising:
controlling the air flow from a portion of the computing environment using at least one portable robot device.
